(19) United States
(12) Patent Application Publication
(10) Pub. No.: US 2012/0306525 A1
(43) Pub. Date: Dec. 6, 2012

(54) Method and Device for Determining the Quantum Efficiency of a Solar Cell

(75) Inventor: Bart Moné, Radebeul (DE)

(73) Assignee: Schueco TF GmbH & Co. KG, Bielefeld (DE)

(21) Appl. No.: 13/510,275

(22) PCT Filed: Sep. 27, 2010
(86) PCT No.: PCT/EP2010/064265

§ 371 Date: Aug. 6, 2012

(30) Foreign Application Priority Data
Nov. 16, 2009 (DE) 10 2009 053 504.7

(51) Int. Cl. G01R 31/26

(52) U.S. Cl. 324/761.01

(57) ABSTRACT

A method for determining the quantum efficiency of a solar cell (11) comprising an active layer sequence (3) is specified, comprising the following steps:
A) providing the active layer sequence (3) comprising at least one optoelectronically active layer (4, 5) which has an absorption spectrum;
B) carrying out a plurality of measurements of photocurrents generated in the optoelectronically active layer (4, 5),
   wherein
      during the plurality of measurements, the photocurrents are generated by light having mutually different illumination spectra,
      the mutually different illumination spectra are differently weighted superimpositions of a plurality of individual spectra (50, 60) having respectively different characteristic wavelengths (51, 61),
      individual spectra (50, 60) having adjacent characteristic wavelengths (51, 61) overlap, and
      each of the different illumination spectra covers the absorption spectrum;
C) determining the quantum efficiency from the plurality of photocurrents and the associated weighted superimpositions.

An apparatus for determining the quantum efficiency of a solar cell (11) is furthermore specified.

The present invention relates to a method for determining the quantum efficiency of a solar cell, and to an apparatus for determining the quantum efficiency of a solar cell.

The quantum efficiency of a solar cell, which is also denoted as spectral sensitivity, indicates how many photons or what light power, depending on the wavelength of the photons, can be absorbed by the solar cell and converted into electric current. It is substantially dependent on the materials of the solar cell, in particular on the active layers, in which photons are converted to electric current. In order to determine the wavelength-dependent quantum efficiency of a solar cell, the latter is usually irradiated with monochromatic light, that is to say with light in a very narrow wavelength range, having a variable wavelength and the current thereby induced in the solar cell is measured. A light source such as, for instance, a halogen lamp and a monochromator for selecting wavelength intervals are usually used for such measurements.

The higher the intended resolution of the measurement, the narrower the wavelength range of the incident light must be. Given a desired high resolution and a corresponding very small spectral width of the incident light, that leads to a very small current induced in the solar cell, such that a long integration time is necessary for each of the measurements, in order to achieve a stable signal. Customary measurement times for determining the quantum efficiency are therefore in the range of from half an hour to one hour.

When measuring the quantum efficiency of a so-called multiple absorber system such as a tandem cell, for instance, wherein two active layers comprising two different materials having different absorption spectra are arranged one above the other and are thereby electrically connected in series, it is possible to measure a photocurrent only when both active layers absorb photons and can thereby generate electron-hole pairs, since it is only then that both active layers are electrically conductive. In this case, the respective electrical conductivity of the active layers is dependent on the charge carrier pairs respectively generated. The measured photocurrent, corresponding to the current which flows through both active layers arranged one above the other, is therefore limited by the lower of the two conductivities. Therefore, if, in known methods, monochromatic light in a wavelength range that can only be absorbed by one of the two active layers is irradiated, then no photocurrent at all would be able to be measured, since the other active layer is not conductive. Therefore, in the case of such methods, it is necessary that, in addition to the monochromatic light, a broadband “bias light”, as it is called, is irradiated onto the solar cell, and serves for additionally generating electron-hole pairs in the active layer that does not absorb the monochromatic light, in order to make said active layer conductive. The bias light is typically generated by means of halogen lamps with suitably chosen band-edge filters.

At least one object of specific embodiments of the present invention is to specify a method for determining the quantum efficiency of a solar cell which can enable a faster and/or simpler measurement. Furthermore, it is an object of specific embodiments to specify an apparatus for determining the quantum efficiency of a solar cell.

These objects are achieved by means of the method and the article comprising the features of the independent patent claims. Advantageous embodiments and developments of the method and of the article are characterized in the dependent claims and are furthermore evident from the following description and the drawings.

A method for determining the quantum efficiency of a solar cell comprising an active layer sequence in accordance with one embodiment comprises, in particular, the following steps:
A) providing the active layer sequence comprising at least one optoelectronically active layer which has an absorption spectrum;
B) carrying out a plurality of measurements of photocurrents generated in the optoelectronically active layer,
   wherein
      during the plurality of measurements, the photocurrents are generated by light having mutually different illumination spectra,
      the mutually different illumination spectra are differently weighted superimpositions of a plurality of individual spectra having respectively different characteristic wavelengths,
      individual spectra having adjacent characteristic wavelengths overlap, and
      each of the different illumination spectra covers the absorption spectrum;
C) determining the quantum efficiency from the plurality of photocurrents and the associated weighted superimpositions.

Here and hereinafter, light can thereby denote electromagnetic radiation in the ultraviolet to infrared wavelength range, and in particular in the wavelength range covered by the absorption spectrum of the optoelectronically active layer.

Thereby, the characteristic wavelength can correspond to the highest-intensity wavelength of an individual spectrum. As an alternative thereto, the characteristic wavelength can also denote the average wavelength of the spectral range covered by the respective individual spectrum. Furthermore, the characteristic wavelength can also denote the average wavelength of an individual spectrum that is weighted by means of the individual spectral intensities.

The solar cell can comprise one or more functional electrical regions which are arranged alongside one another and connected in series along one or both main extension directions of the solar cell or of the at least one optoelectronically active layer, such that the area to be irradiated by the light is formed by the areas of the functional electrical regions. A solar cell comprising a plurality of functional electrical regions can also be referred to as a solar panel.

In the method described here, an illumination spectrum that is a superimposition of a plurality of individual spectra is generated for each measurement of a photocurrent generated in the optoelectronically active layer. As a result, the light irradiated onto the optoelectronically active layer has a higher intensity than is possible in the case of measuring methods customary in the prior art. Consequently, it is advantageously possible to considerably reduce the measurement time of each of the plurality of measurements and also the total measurement time necessary in the case of the present method in order to determine the quantum efficiency of a solar cell, in comparison with known measuring methods.

In particular, the illumination spectrum can be generated by an illumination device comprising a plurality of light-emitting diodes. In this case, each of the individual spectra is generated by a respective light-emitting diode or a respective group of light-emitting diodes of identical type. In this case, a light-emitting diode (LED) has the advantage that the emitted light intensity when a current is applied to the LED is very fast with regard to the emitted light power and stable with regard to the operating temperature, and the LED therefore emits individual spectra with high reproducibility depending on the current and temperature.

In accordance with a further embodiment, an illumination device for emitting light having different illumination spectra according to the abovementioned method comprises, in particular, a plurality of light-emitting diodes, wherein
each of the plurality of light-emitting diodes emits light having a respective individual spectrum having a characteristic wavelength,
the different illumination spectra are differently weighted superimpositions of the individual spectra, and
individual spectra having adjacent characteristic wavelengths overlap.

In accordance with a further embodiment, an apparatus for determining the quantum efficiency of a solar cell according to the abovementioned method comprises, in particular,
an abovementioned illumination device, and
an electronic calculating unit for carrying out method steps B and C.

In this case, the electronic calculating unit can, for example, control the currents impressed on the individual LEDs and thus also generate the mutually different illumination spectra. The currents used for each of the illumination spectra and the photocurrent respectively generated as a result can be stored in the calculating unit and used for carrying out method step C.

The features and embodiments described below relate equally to the method and also to the above-described illumination device and the apparatus.

In accordance with a further embodiment, in method step B, the differently weighted superimpositions of the individual spectra are formed by different combinations of intensities of the individual spectra that are in each case different than zero. That can mean, in particular, that for the different illumination spectra in each case none of the individual spectra has such a low intensity that said individual spectrum cannot contribute to the photocurrent generated in the optoelectronically active layer. This has the advantage that each of the illumination spectra has a continuous spectrum in the range of the total spectrum provided by the individual spectra. Consequently, none of the different illumination spectra has a spectral component equal to zero either, such that all spectral components of the illumination spectra in each case contribute to the individual measurements. This can facilitate and simplify the determination of the quantum efficiency in method step C.

Furthermore, the total spectrum covering the absorption spectrum of the active layer sequence can ensure that, by way of example, even in tandem cells or other multiple absorber systems comprising more than one active layer having mutually different layer-specific absorption spectra, all of the more than one active layer can absorb light and therefore generate charge carrier pairs, such that all of the more than one active layer are also electrically conductive. Consequently, this can ensure that during each of the measurements in method step B a photocurrent is measurable for example even without the above-described bias light that is necessary in the prior art.

Furthermore, in method step B, for providing each of the different illumination spectra, each of the plurality of individual spectra can have an intensity that is selected from a respectively defined group having a number of discrete intensities that are different than zero. If the individual spectra are generated by LEDs, for example, then this can mean that for each LED a number of previously defined current intensities are selected which lead to individual spectra having a corresponding number of different intensities. Generating an illumination spectrum then involves selecting for each individual spectrum a current intensity and thus the corresponding intensity from the associated group. Generating an illumination spectrum that is different therefrom involves selecting a different combination of intensities from the groups of individual spectra.

On account of the high stability and reproducibility of the individual spectra and the individual spectrum intensities of an LED depending on the current respectively applied, it is possible to measure the current-dependent individual spectra and individual spectrum intensities before carrying out method step B, and to store them for example in the calculating unit.

In the course of the measurements in method step B, a corresponding multiplet of LED currents or individual spectra and individual spectrum intensities is then assigned to each illumination spectrum and thus also to each measured photocurrent. From the individual spectra used in the plurality of measurements, and the photocurrents respectively generated in this case, there substantially arises a solvable linear or nonlinear system, from which the wavelength-dependent quantum efficiency of the active layer sequences and thus of the solar cell can be determined by means of an estimation, calculation or approximation method, for example by means of a linear or nonlinear optimization method, a spline interpolation method or a genetic algorithm. In this case, the real wavelength-dependent quantum efficiency of the solar cell can be determined proceeding for example from the theoretical absorption spectrum of the optoelectronically active layer, said theoretical absorption spectrum being known on account of the materials used.

Furthermore, in method step B, the differently weighted superimpositions can be chosen randomly. That means that each multiplet of individual spectra is formed by a random selection from the previously chosen individual spectra of the defined groups. That has the advantage, when carrying out the method for a plurality of solar cells, that the individual measurements are independent of one another, such that systematic errors that can possibly occur in the case of a method sequence that is always identical from solar cell to solar cell can be avoided.

By virtue of the higher light intensity of the different illumination spectra in comparison with the prior art, higher currents can be generated in the active layer sequence comprising the at least one optoelectronically active layer, such that a shorter measurement time in comparison with the prior art is possible. Advantageously, in the method described here, an individual measurement of method step B can have a duration of less than or equal to ten milliseconds. This can be possible particularly when the individual spectra are generated by LEDs which are stable thermally and with regard to their emission power typically after one or a few milliseconds after switch-on.

Furthermore, in method step B, at least 100 measurements can be carried out. The higher the number of measurements in method step B, the higher, too, the resolution with which the quantum efficiency of the solar cell can be determined. On account of the abovementioned short measurement time for the individual measurements of method step B, the total measurement time necessary for carrying out method step B in its entirety can still be very short, even in the case of many measurements of this type. It can be particularly advantageous if 500 measurements, for example, are carried out in method step B.

By virtue of the fast measuring method of the method described here, method steps B and C can already be carried out before the solar cell is completed. That can mean, in particular, that although the active layer sequence is provided in method step A, the solar cell is not yet completed and, for example, does not yet have an encapsulation nor a covering glass. The method described here can therefore be carried out within the production process for the solar cell without appreciably delaying the production process for the solar cell. By virtue of the short total measurement time of the method described here, in this case it is possible to avoid degradation of the active layer sequence while carrying out the method.

Besides the number of individual measurements in method step B, the resolution of the quantum efficiency achievable in method step B, depending on the wavelength, is also determined by the number of individual spectra. It is therefore particularly advantageous if the different illumination spectra are differently weighted superimpositions of greater than or equal to five and less than or equal to 20 and particularly preferably about ten individual spectra. It has furthermore been ascertained that it is particularly advantageous for the method described here if individual spectra having adjacent characteristic wavelengths have an overlap of greater than or equal to five percent and less than or equal to 20 percent and particularly preferably of about ten percent. An overlap of about ten percent, for example, means in this case that the spectral components which make up about ten percent of the total intensity of an individual spectrum lie in the wavelength range of an adjacent individual spectrum. By virtue of the fact that the individual spectra having respectively adjacent characteristic wavelengths overlap, it can be ensured that the different illumination spectra in the entire wavelength range covered by them have only spectral components that are different than zero. As a result, during each of the individual measurements in method step B each spectral component of the different illumination spectra can contribute to the photocurrent respectively measured.

In the case of a solar cell comprising a plurality of functional electrical regions which are arranged alongside one another and interconnected with one another along the area of the solar cell or the at least one optoelectronically active layer, the photocurrent of one such functional electrical region or of a plurality or all of the functional electrical regions can be measured simultaneously. Consequently, a spatially resolved quantum efficiency can also be determinable by means of a measurement of the photocurrent by means of method step B successively in the individual functional active regions.

Furthermore, the light having the different illumination spectra can be irradiated onto at least five percent of the area of the optoelectronically active layer. That area of the active layer sequence comprising the at least one optoelectronically active layer which is illuminated by the illumination device can in this case have a continuous region, for example in the form of a strip having the full width of the optoelectronically active layer, or else a region in the form of different non-continuous regions.

In particular, the optoelectronic active layer can have, along at least one main extension direction of the optoelectronically active layer, a plurality of functional electrical regions that are arranged alongside one another and interconnected with one another, and the light having the different illumination spectra can be irradiated onto more than one functional electrical region of the optoelectronically active layer. An abovementioned illuminated strip can cover, for example, in one dimension the full width of the optoelectronically active layer and in a second dimension at least the dimension of one functional electrical region and preferably of a plurality of functional electrical regions, for instance 10 thereof.

A functional electrical region can have a dimension of greater than or equal to 7 mm and less than or equal to 20 mm and preferably of about 10 mm.

Furthermore, at least half of the optoelectronically active layer and particularly preferably the total area of the optoelectronically active layer can be illuminated with the light having the different illumination spectra in method step B. A quantum efficiency averaged over the entire area of the active layer sequence can advantageously be determined as a result.

Particularly in the case of solar cells or solar panels comprising a plurality of functional electrical regions that are arranged alongside one another and connected in series, it is necessary in the case of methods known in the prior art by means of monochromatic light to restrict the illuminated region also such a functional electrical region, since stray light that can be incident in adjacent functional electrical regions would corrupt the measurement. In the case of the method described here, by contrast, this problem can be avoided since it is possible to illuminate a larger continuous region. The continuous illuminated region can cover, in particular, a plurality of functional electrical regions.

The method described here can make it possible to measure the quantum efficiency of the entire solar cell even in the case of large-area solar cells having areas of more than one square meter, and in particular even of more than 5 m². As a result, within the manufacturing process for the solar cell, monitoring control with regard to the entire active area is possible.

In order to achieve as uniform illumination as possible of the optoelectronically active layer, the illumination device can furthermore comprise an optical diffuser, for example a diffusing plate, which is disposed downstream of the plurality of light-emitting diodes in the emission direction.

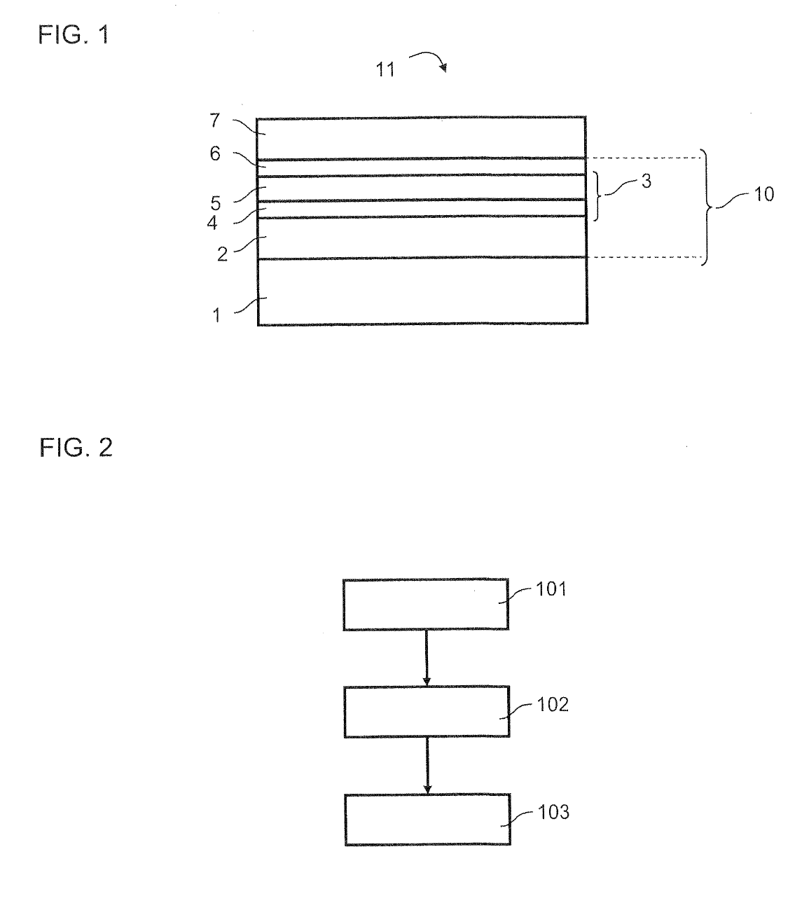

Further advantages and advantageous embodiments and developments of the invention will become apparent from the embodiments described below in conjunction with FIGS. 1 to 4.

In the figures:

FIG. 1 shows a schematic illustration of a solar cell,

FIG. 2 shows a schematic illustration of a method in accordance with one exemplary embodiment,

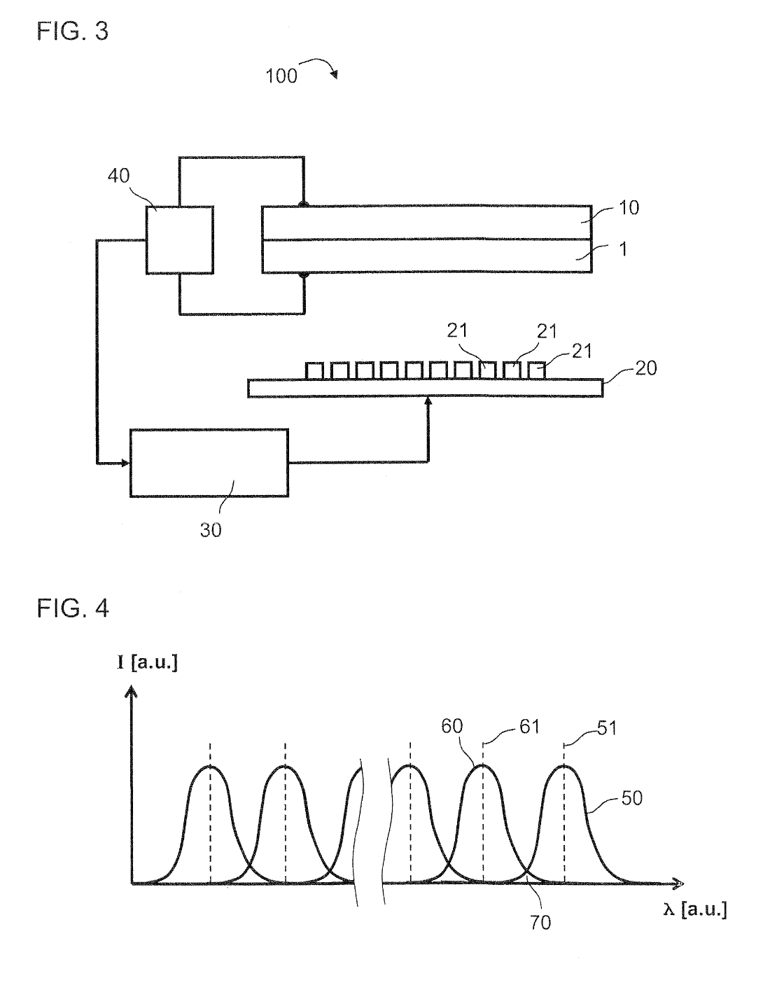

FIG. 3 shows a schematic illustration of an apparatus in accordance with a further exemplary embodiment, and

FIG. 4 shows a schematic illustration of individual spectra in accordance with a further exemplary embodiment.

In the exemplary embodiments and figures, identical or identically acting component parts can be provided in each case with the same reference signs. The illustrated elements and their size relationships among one another should not be regarded as true to scale, in principle; rather, individual elements such as, for example, layers, structural parts, components and regions may be illustrated with exaggerated thickness or size dimensions in order to enable better illustration and/or in order to afford a better understanding.

FIG. 1 shows an example of a solar cell 11, the quantum efficiency of which can be determined by the method described here.

The solar cell 11 comprises a substrate 1, on which an optoelectronically active layer sequence 3 comprising two optoelectronically active layers 4, 5 is applied between two electrodes 2, 6. In this case, the electrodes 2, 6 and the optoelectronically active layer sequence 3 form the active layer sequence 10 of the solar cell 11. A covering layer 7 for protecting the active layer sequence 10 is applied above the active layer sequence 10. The substrate consists of glass having a typical thickness of one or a plurality of millimeters, on which a transparent conductive oxide, for example tin oxide, is applied as electrode 2. The optoelectronically active layer sequence 3 comprises an optoelectronically active layer 4 composed of amorphous silicon and a further optoelectronically active layer 5 composed of microcrystalline silicon. The optoelectronically active layers 4, 5 form, as a result of corresponding dopings, a series connection of two p-i-n junctions, in each of which photons can be absorbed with formation of electron-hole pairs. As a result of this known tandem construction, as it is called, it is possible to achieve a widening of the absorption spectrum and thus an improvement in the quantum efficiency of the solar cell 11. The electrode 6 on the optoelectronically active layer sequence 3 comprises a metal layer sequence. The covering layer 7 comprises a plastic layer on the electrode 6 and thereabove a further glass layer, which can be embodied like the substrate 1, for encapsulating the solar cell 11.

During the operation of the solar cell 11, light, for example sunlight, is incident from outside through the substrate 1 and the electrode 2 on the optoelectronically active layer sequence 3 and can be absorbed in the optoelectronically active layers 4, 5 with generation of a photocurrent.

Furthermore, the solar cell can comprise a plurality of functional electrical regions (not shown) which are arranged alongside one another in a matrix-like manner along the layer plane and are electrically interconnected with one another. Each of the functionally electrical regions can have a dimension of greater than or equal to 7 mm and less than or equal to 20 mm and particularly preferably of about 10 mm.

A solar cell embodied in this way can have, for example, an area of one meter by one meter, or even an area of several square meters, for instance 5.7 m².

The method described below in accordance with the exemplary embodiment in FIG. 2 can be performed simultaneously at individual functional electrical regions or at a plurality of functional electrical regions, such that a spatially resolved determination of the quantum efficiency is also possible.

Alternatively or additionally, the solar cell can also comprise one or a plurality of active layers based on one or a plurality of the following materials: Si—Ge alloy, CdTe, ternary or quaternary materials based on copper indium gallium sulfide (so-called CIGS materials) in particular with or without gallium.

Furthermore, the solar cell can also be embodied as a multiabsorber system comprising more than two active layers. Furthermore, the solar cell can also be based on crystalline material based on one of the abovementioned materials.

FIG. 2 shows an exemplary embodiment of a method for determining the quantum efficiency of a solar cell, for instance of the solar cell 11 shown above, but also of any other solar cell. In this case, a first method step A, identified by the reference sign 101, involves providing an active layer sequence comprising at least one optoelectronically active layer, which, by way of example, is embodied in accordance with the layer sequence 3 of the solar cell 11 described above and which has an absorption spectrum.

A further method step B, identified by the reference sign 102, involves carrying out a plurality of measurements, wherein a plurality of photocurrents generated in the optoelectronically active layer by light having mutually different illumination spectra are measured. The different illumination spectra are formed by weighted superimpositions of in each case a plurality of individual spectra having in each case different characteristic wavelengths, wherein individual spectra having adjacent characteristic wavelengths overlap and the illumination spectra in each case cover the absorption spectrum of the at least one optoelectronically active layer.

A further method step C, identified by the reference sign 103, involves determining the quantum efficiency from the plurality of measured photocurrents and the associated weighted superimpositions.

Further features of the method are explained below, in particular in connection with the apparatus 100 in accordance with the exemplary embodiment in FIG. 3.

The quantum efficiency of a solar cell, for example of the solar cell 11 in FIG. 1, can be determined according to the above-described method during the method for producing the solar cell, in particular as early as after applying the active layer sequence 10 on the substrate 1 and before applying the covering layer 7, by means of the apparatus 100 in accordance with FIG. 3. In this case, the apparatus 100 can be arranged directly in the production line for producing the solar cell 11. FIG. 3 therefore shows purely schematically a solar cell that has not yet been completed in the form of the active layer sequence 10 on the substrate 1, which is provided in method step A identified by the reference sign 101 in FIG. 2.

The apparatus 100 shown in the exemplary embodiment in FIG. 3 comprises an illumination device 20, which has a plurality of light-emitting diodes (LEDs) 21, only some of which are provided with reference signs in FIG. 3 for the sake of clarity. Each of the LEDs 21 generates light having an individual spectrum having a characteristic wavelength, wherein the respective characteristic wavelengths are different from one another and individual spectra having adjacent characteristic wavelengths overlap.

In order to facilitate understanding, FIG. 4 shows in a graph individual spectra indicated purely by way of example, only the individual spectra 50 and 60 of which are provided with reference signs for the sake of clarity. The graph has the wavelength as horizontal axis and the intensity as vertical axis, in each case in arbitrary units. The individual spectrum 50 has a characteristic wavelength 51, while the individual spectrum 60 has a characteristic wavelength 61. The characteristic wavelengths 51, 61 are different from one another. The further characteristic wavelengths of the other individual spectra, which are likewise in each case different from said characteristic wavelengths 51, 61 and among one another, are indicated by means of the dashed lines.

Thereby, each of the LEDs 21 of the illumination device 20 generates one of the individual spectra. As an alternative thereto, it is also possible for in each case a plurality of LEDs 21 to be combined in a group, wherein all LEDs of a group in each case generate the same individual spectrum. The intensity of the individual spectra can be increased as a result. By virtue of the simultaneous emission of light by all LEDs 21 of the illumination device 20, the illumination device 20 can emit an illumination spectrum which corresponds to the superimposition of the plurality of the individual spectra.

The number of individual spectra and the respective spectral width and wavelength range thereof can in this case be adapted to the desired measurement resolution of the apparatus 100. The larger the number of individual spectra and the narrower each of the individual spectra is in each case, the more possibilities there are for generating the mutually different illumination spectra in method step B, and the higher the resolution that can be achieved when determining the quantum efficiency. With a larger number of individual spectra however, the outlay also increases when determining the quantum efficiency. Therefore, a number of greater than or equal to 5 and less than or equal to 20 individual spectra has proved to be advantageous, a number of 10 individual spectra being particularly advantageous. In the exemplary embodiment shown, the illumination device 20 therefore has 10 LEDs 21.

The spectral width and the respective wavelength range of individual spectra having adjacent characteristic wavelengths, such as the individual spectra 50, 60, for instance, is chosen in such a way that they overlap. In this case, the overlap 70 designates the wavelength range contained in adjacent individual spectra 50, 60.

The larger the overlap 70, the more similar, however, the contribution of two adjacent individual spectra to the measured photocurrent. The smaller the overlap 70, the greater, in turn, the risk of an illumination spectrum having spectral components which make no or hardly any contribution to the photocurrent and thus make it more difficult to determine the quantum efficiency in this wavelength range. Therefore, an overlap of greater than or equal to 5% and less than or equal to 20% has proved to be advantageous, an overlap of 10% being particularly advantageous. As a result, a uniform distribution of the individual spectra over the entire wavelength range of the illumination spectra is simultaneously achieved.

By means of different driving of the respective LEDs 21, for example by means of respectively different current impression, the individual spectra are generated with different intensities, such that different illumination spectra which correspond to differently weighted superimpositions of the plurality of individual spectra can be emitted by the illumination device 20. In this case, LEDs of the illumination device 20 are driven by means of the electronic calculating unit 30 of the apparatus 100, in which a group having a number of discrete current intensities that are different than zero is stored for each of the LEDs. Consequently, the illumination device 20 can emit each of the individual spectra with different intensities selected beforehand, such that the differently weighted superimpositions for generating different illumination spectra are made possible by means of different combinations. In the exemplary embodiment shown, the electronic calculating unit 30 selects random combinations of the individual intensities of the individual spectra, such that the illumination device 20 can emit a plurality of mutually different, randomly chosen illumination spectra.

In order to be able to determine a quantum efficiency averaged as far as possible over the entire active layer sequence 10, the illumination device 20 illuminates at least 10% of the active area of the active layer sequence 10 and preferably a region extending over the entire width or over a plurality of partial regions of the active area. Particularly preferably, the illumination device 20 illuminates the entire active area of the active layer sequence 10. In order to achieve as uniform illumination as possible of the active area of the active layer sequence 10, the illumination device 20 can comprise an optical diffuser, for example a diffusing plate, (not shown), which is disposed downstream of the LEDs in the emission direction.

The photocurrent generated by the light having an illumination spectrum in the active layer sequence 10 is measured by the measuring device 40 and forwarded to the electronic calculating unit 30. The measuring unit 40 can also be integrated in the electronic calculating unit 30.

The electronic calculating unit is furthermore embodied in such a way that, with respect to the previously defined current intensities, the individual spectra respectively generated by the LEDs 21 are stored and a measured photocurrent with the associated individual spectra and their intensities, that is to say the associated weighted superimposition, are stored.

On account of the superimposition of the individual spectra, the intensity of the illumination spectra is high enough to measure the generated photocurrents in each case in a measurement time of less than or equal to 10 ms per measurement. As a result, a large number of measurements can be carried out in the exemplary embodiment shown. The larger the number of measurements in this case, the greater the resolution that can be achieved when determining the quantum efficiency. A number of greater than or equal to 100 and less than or equal to 10 000 measurements has proved to be advantageous. A number of 500 measurements is particularly advantageous.

From the individual spectra which are used in the plurality of measurements and are stored in the calculating unit 30, and the superimpositions of said spectra and the photocurrents respectively generated in this case, the wavelength-dependent quantum efficiency of the active layer sequence 10 and thus of the solar cell is determined with the aid of the calculating unit 30 in an estimation, calculation or approximation method, for example by means of a linear or a nonlinear optimization method, a spline interpolation method or a genetic algorithm, wherein the theoretical absorption curve of the materials and layers used in the active layer sequence 10 is taken as a basis and is adapted to the real quantum efficiency curve by one of the abovementioned methods.

As an alternative or in addition to the features described in conjunction with FIGS. 1 to 4, the exemplary embodiments shown can have further, alternative or additional features as described in the general part.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

### LIST OF REFERENCE SIGNS

1 Substrate

2 Electrode

3 Optoelectronically active layer sequence

4 Optoelectronically active layer

5 Optoelectronically active layer

6 Electrode

7 Covering layer

10 Active layer sequence

11 Solar cell (11)

20 Illumination device

21 LED

30 Electronic calculating unit

40 Measuring unit

50 Individual spectrum

51 Characteristic wavelength

60 Individual spectrum

61 Characteristic wavelength

70 Overlap

100 Apparatus

101 Method step

102 Method step

103 Method step

1. A method for determining the quantum efficiency of a solar cell (11) comprising an active layer sequence (3), comprising the following steps:
A) providing the active layer sequence (3) comprising at least one optoelectronically active layer (4, 5) which has an absorption spectrum;
B) carrying out a plurality of measurements of photocurrents generated in the optoelectronically active layer (4, 5),
wherein
during the plurality of measurements, the photocurrents are generated by light having mutually different illumination spectra,
the mutually different illumination spectra are differently weighted superimpositions of a plurality of individual spectra (50, 60) having respectively different characteristic wavelengths (51, 61),
individual spectra (50, 60) having adjacent characteristic wavelengths (51, 61) overlap, and
each of the different illumination spectra covers the absorption spectrum;
C) determining the quantum efficiency from the plurality of photocurrents and the associated weighted superimpositions.

2-12. (canceled)
